(19) United States
(12) Patent Application Publication
(10) Pub. No.: US 2013/0247816 A1
(43) Pub. Date: Sep. 26, 2013

(54) FILM-FORMING APPARATUS FOR THE FORMATION OF SILICON CARBIDE AND FILM-FORMING METHOD FOR THE FORMATION OF SILICON CARBIDE

(71) Applicants: NUFLARE TECHNOLOGY, INC., Shizuoka (JP); DENSO CORPORATION, Aichi (JP)

(72) Inventors: Kunihiko SUZUKI, Shizuoka (JP); Yuusuke Sato, Tokyo (JP); Hideki Ito, Kanagawa (JP); Hidekazu Tsuchida, Kanagawa (JP); Isaho Kamata, Tokyo (JP); Masahiko Ito, Kanagawa (JP); Masami Naito, Aichi (JP)

(73) Assignees: Denso Corporation, Aichi (JP); NuFlare Technology, Inc., Shizuoka (JP)

(21) Appl. No.: 13/838,376

(22) Filed: Mar. 15, 2013

(30) Foreign Application Priority Data
Mar. 22, 2012 (JP) 2012-066300
Mar. 4, 2013 (JP) 2013-042248

(51) Int. Cl. H01L 21/02

(52) U.S. Cl. CPC H01L 21/02529
USPC 117/86; 118/712; 117/89

(57) ABSTRACT

A film-forming apparatus and method for the formation of silicon carbide comprising, a film-forming chamber to which a reaction gas is supplied, a temperature-measuring unit which measures a temperature within the chamber, a plurality of heating units arranged inside the chamber, an output control unit which independently controls outputs of the plurality of heating units, a substrate-transferring unit which transfers a substrate into, and out of the chamber, wherein the output control unit turns off or lowers at least one output of the plurality of heating units when the film forming process is completed, when the temperature measured by the temperature-measuring unit reaches a temperature at which the substrate-transferring unit is operable within the chamber, then at least one output of the plurality of heating units turned off or lowered, is turned on or raised, and the substrate is transferred out of the film-forming chamber by the substrate-transferring unit.

The entire disclosure of the Japanese Patent Applications No. 2012-066300, filed on Mar. 22, 2012 and No. 2013-042248, filed on Mar. 4, 2013 including specification, claims, drawings, and summary, on which the Convention priority of the present application is based, are incorporated herein in its entirety.

### FIELD OF THE INVENTION

The present invention relates to a film-forming apparatus for the formation of silicon carbide and a film-forming method for the formation of silicon carbide.

### BACKGROUND

Epitaxial growth technique is conventionally used to produce a semiconductor device such as a power device (e.g., IGBT (Insulated Gate Bipolar Transistor)) requiring a relatively thick crystalline film.

In the case of vapor-phase epitaxy used in an epitaxial growth technique, a substrate is placed inside a film-forming chamber maintained at an atmospheric pressure or a reduced pressure, and a reaction gas is supplied into the film-forming chamber while the substrate is heated. As a result of this process, a pyrolytic reaction or a hydrogen reduction reaction of the reaction gas occurs on the surface of the substrate so that an epitaxial film is formed on the substrate. The gas generated by the reaction, as well as the gas not used, is exhausted through the outer portion of the chamber. After the epitaxial film is formed on the substrate, the substrate is then carried out from the chamber. Another substrate is then placed into the chamber, and then an epitaxial film will be formed on that substrate.

In order to produce a thick epitaxial film in high yield, a fresh reaction gas needs to be continuously brought into contact with the surface of a uniformly heated substrate to increase a film-forming rate. Therefore, in the case of a conventional film-forming apparatus, a film is epitaxially grown on a wafer while the wafer is rotated at a high speed (see, for example, Japanese Patent Application Laid-Open No. 2009-170676).

In a conventional film-forming apparatus, a rotating unit is positioned in a film-forming chamber, and a substrate is positioned on a ring-shaped holder arranged on the top-surface of the rotating unit. A resistive heater functioning as an inner heater is positioned below the holder.

When the film forming process performed on the substrate has been completed, the substrate is removed from the film-forming chamber. Since the temperature within the film-forming chamber immediately after the film forming process is very high, it is necessary to remove the substrate after the temperature within the film-forming chamber has lowered.

After the substrate has been removed from the film-forming chamber, a substrate that will be next subjected to the film forming process is transferred into the film-forming chamber. The temperature within the film-forming chamber is increased up to a temperature required for the film forming process. However, it takes time in order to raise the temperature that was lowered, up to the film-forming temperature. Therefore, the time required from completion of the film forming process to the next film forming process results in a lowering a throughput in the manufacture process of semiconductor devices.

For example, a substrate is heated to approximately 1200° C. in film formation of a Si (silicon) vapor deposition film. After completion of the film formation, the heater is turned off to lower the temperature within the film-forming chamber to a predetermined temperature and the substrate is then removed from the film-forming chamber. Next, another substrate is transferred into the film-forming chamber and the heater is turned on. However, since the temperature within the film-forming chamber is considerably low in this stage, a long time is required for the temperature to rise to 1200° C.

Further, in recent years, attention has been given to SiC (silicon carbide) as a semiconductor material to be used in high-voltage power semiconductor devices, the film-forming temperature is required to be 1500° C. or higher. Therefore, after the temperature within the film-forming chamber has been lowered in order to remove the substrate, a time required to raise the temperature to the film-forming temperature becomes longer than that in the case of the Si vapor deposition film. Therefore, lowering of the throughput is further increased.

The present invention has been made to address the above issues. That is, an object of the present invention is to provide a film-forming apparatus and a film-forming method for the formation of silicon carbide in that the time elapsing from completion of the film forming process to performance of the next film forming process can be suppressed to a minimum, thus resulting in an improvement in throughput.

Other challenges and advantages of the present invention are apparent from the following description.

### SUMMARY OF THE INVENTION

According to one aspect of the present invention, a film-forming apparatus for the formation of silicon carbide comprising, a film-forming chamber to which a reaction gas is supplied, where a film forming process is performed, a temperature-measuring unit which measures a temperature within the film-forming chamber, a plurality of heating units which are arranged inside the film-forming chamber, an output control unit which controls respective outputs of the plurality of heating units independently, a substrate-transferring unit which transfers a substrate to which a film forming process of silicon carbide is performed into, and out of the chamber, and a susceptor on which the substrate is placed, the susceptor being disposed within the film-forming chamber, wherein the output control unit turns off or lowers at least one output of the plurality of heating units when the film forming process to the substrate is completed, when the temperature measured by the temperature-measuring unit reaches a temperature at which the substrate-transferring unit is operable within the film-forming chamber, then at least one output of the plurality of heating units which has been turned off or lowered, is turned on or raised, and the substrate to which the film forming process has been performed is transferred out of the film-forming chamber by the substrate-transferring unit.

According to another aspect of the present invention, a film-forming method for the formation of silicon carbide, wherein, a reaction gas is supplied into a film-forming chamber and a film of silicon carbide is formed on a substrate while the substrate is being heated by a plurality of heating units; after the formation of a silicon carbide on a substrate, at least one output of the plurality of heating units is turned off or lowered, when the temperature within the film-forming chamber reaches T1 or lower, at least one output of the plurality of heating units which has been turned off or lowered, is turned on or raised, and a substrate-transferring unit then enters the film-forming chamber, when the temperature within the film-forming chamber reaches T2 (incidentally, T1>T2) or lower, the substrate is transferred out of the film-forming chamber by the substrate-transferring unit, and another substrate is then transferred into the film-forming chamber by the substrate-transferring unit and the outputs of the remaining heating units are turned on or raised.

### BRIEF DESCRIPTION OF THE DRAWINGS

FIG. 1 is a schematic cross-section of a film-forming apparatus according to the present embodiment.

FIG. 2 is a cross-sectional view of a chamber in the film forming apparatus, as another example according to the first embodiment.

FIG. 3 is a cross-sectional view of a chamber in the film forming apparatus, as another example according to the present embodiment.

FIG. 4 is a plane view showing the construction of a film forming apparatus 100.

FIG. 5 is a diagram showing the relationship among control systems in the film-forming apparatus 101.

FIG. 6 is a graph illustratively showing a temporal change of the measurement result obtained by the temperature-measuring unit 400.

FIG. 7 is a graph showing a relationship between the outputs of the respective heaters and time.

FIG. 8 is a flowchart of a film forming method according to the second embodiment.

FIG. 9 is a graph of a comparative example of this embodiment, and it illustratively shows the temporal change of the measurement result obtained by the temperature-measuring unit 400.

FIG. 10 is a plane view showing an arrangement of the sensor of the film-forming apparatus in FIG. 1.

FIG. 11 shows a relationship between the control systems of a film forming apparatus in FIG. 10.

### DETAILED DESCRIPTION OF THE INVENTION

### Embodiment 1

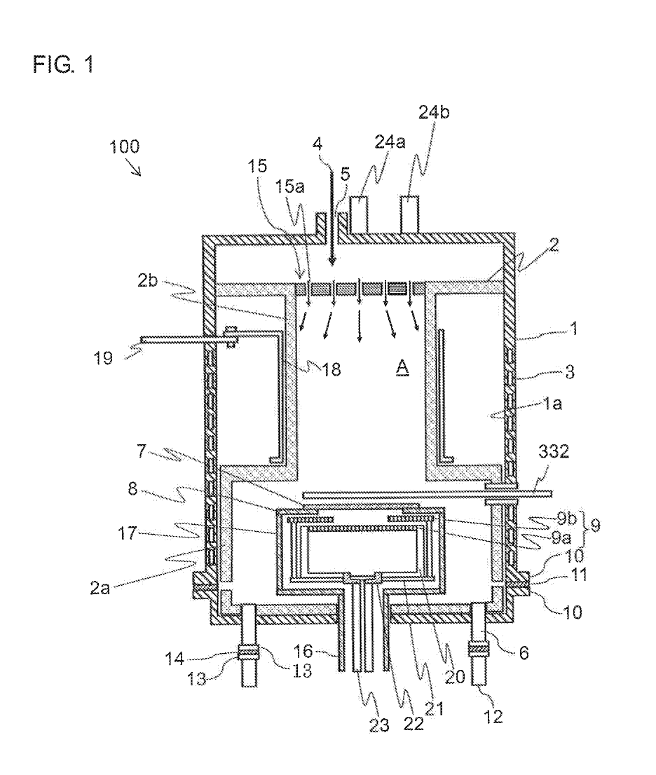

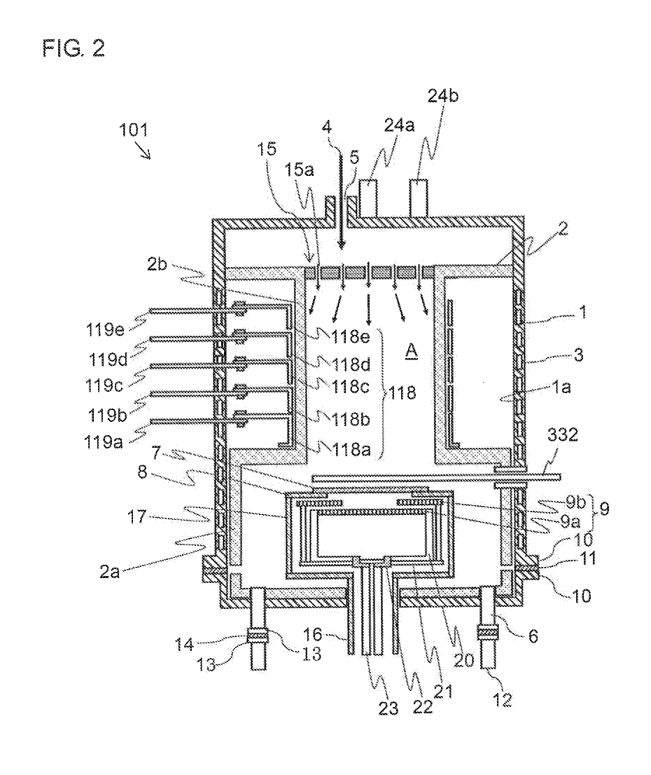

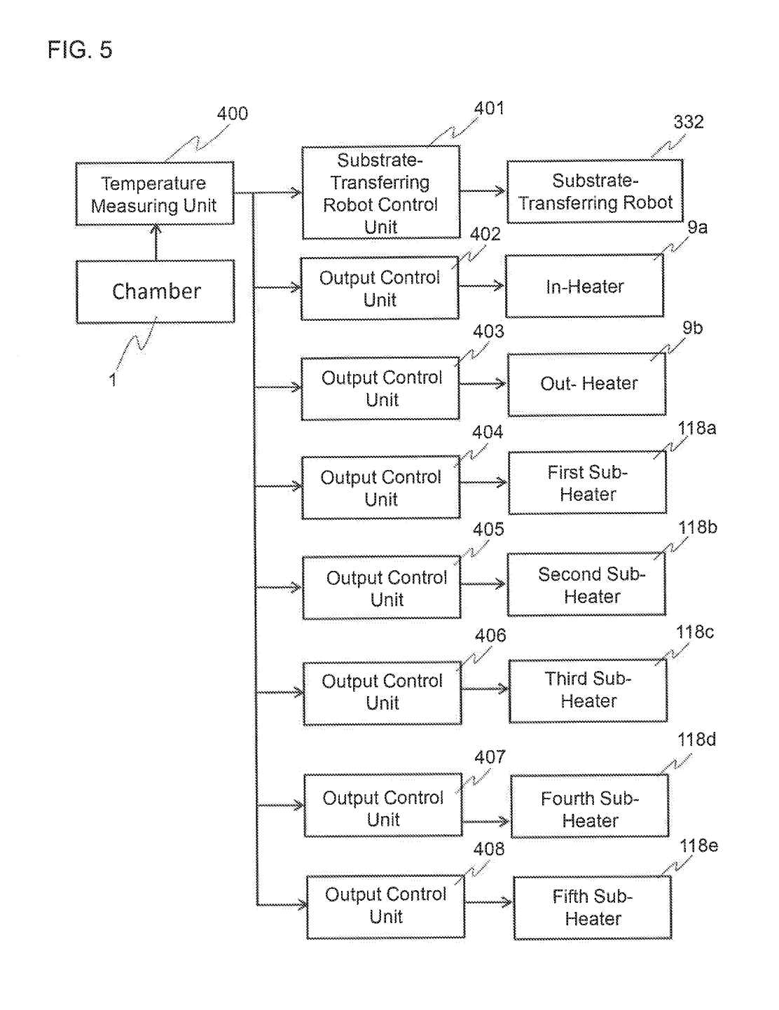

FIG. 1 is a schematic cross section of a film-forming apparatus according to the present embodiment. For example, the control system is substantially same as a film-forming apparatus 101 of FIG. 2 explained using FIG. 5; therefore the control system is not shown in FIG. 1. The scale of this diagram is different from an actual apparatus so that each component is visible clearly.

As shown in FIG. 1, the film-forming apparatus 100 includes a chamber 1 as a film-forming chamber, a hollow tubular liner 2 that covers and protects the inner wall of the chamber 1, flow paths 3 through which cooling water flows to cool the chamber 1, a supply portion 5 for introducing a reaction gas 4, a discharge portion 6 that discharges the reaction gas 4 subjected to reaction, a susceptor 8 that supports the substrate 7 placed thereon, a flange portion 10 that connects upper and lower sections of the chamber 1 with each other, a gasket 11 that seals the flange portion 10, a flange portion 13 that connects the gas discharge portion 6 to a pipe 12, the pipe 12 is used for discharging the gas out of the chamber 1, and a gasket 14 that seals the flange portion 13. These gaskets 11 and 14 are preferably made of fluorine-containing rubber, which have an allowable temperature limit of approximately 300° C.

The liner 2 is provided to separate the inner wall 1a of the chamber 1 from the space A in which the film will be formed on the substrate 7. The inner wall 1a of the chamber 1 is made of stainless steel. Therefore, the liner 2 has the effect of preventing erosion of the inner wall 1a of the chamber 1 by the reaction gas 4.

The liner 2 is made of a material having very high heat resistance, as the film-forming process is performed under high temperature. For example, a SiC member or a member formed by coating carbon with SiC or TaC can be used.

In the present embodiment, the liner 2 is separated into a body portion 2a and a top portion 2b for ease of explanation. The top portion 2b is a unit in which the susceptor 8 is placed. The top portion 2b has a smaller inner diameter than the body portion 2a. The liner 2 consists of the body portion 2a and the top portion 2b combined into one whole portion. The top portion 2b is positioned above the body portion 2a.

A shower plate 15 is fitted into the upper opening of the top portion 2b. The shower plate 15 functions as a flow-straightening vane for uniformly supplying the reaction gas 4 to the surface of the substrate 7. The shower plate 15 has a plurality of through-holes 15a thereon. When the reaction gas 4 is supplied from the supply portion 5 into the film-forming chamber 1, the reaction gas 4 flows downward to the substrate 7 through the through-holes 15a. It is preferable that the reaction gas 4 be efficiently focused on the surface of the substrate 7 without wastage. Accordingly, the inner diameter of the top portion 2b is designed so as to be smaller than the body portion 2a. Specifically the inner diameter of the top portion 2b is determined in consideration of the position of the through-holes 15a and the size of the substrate 7.

The susceptor 8 for supporting the substrate 7 is a ring-shaped susceptor, and is positioned in the film-forming chamber 1, specifically, in the body portion 2a of the liner 2. In order to form a SiC epitaxial film, the temperature of the substrate 7 needs to be 1500° C. or higher. For this reason, the susceptor 8 needs to be made of highly heat-resistant material. A susceptor 8 obtained by coating the surface of isotropic graphite with SiC or TaC by CVD (Chemical Vapor Deposition) can be used (as one example). The shape of the susceptor 8 is not particularly limited as long as the substrate 7 can be placed on the susceptor 8, and may be designed as required. For example, the susceptor may be a disk shape.

The rotating shaft 16 and the rotating cylinder 17 positioned on the top of the rotating shaft 16 are placed in the body portion 2a of the liner 2. The susceptor 8 is attached to the rotating cylinder 17. The rotating shaft 16 is rotated, and then the susceptor 8 is rotated via the rotating cylinder 17. When the film-forming process is performed, the substrate 7 is placed on the susceptor 8, and the substrate 7 is rotated along with the susceptor 8.

A pin (not shown), capable of moving in an up and down direction is provided in the rotating shaft 16. The end of the pin extends to a substrate rising means (not shown) provided at the bottom of the rotating shaft 16. The pin can be moved up and down by the substrate rising means. The pin is used when the substrate 7 is transferred into and out of the chamber 1. The pin supports the bottom of the substrate 7, and then rises to move the substrate 101 away from the susceptor 8. The substrate 7 is then positioned above the rotating portion 104 separate from the susceptor 8 by the pin, allowing a transfer robot 332 to remove the substrate 7. The transfer robot 332 corresponds to a substrate transfer unit in the present invention.

The reaction gas 4 passing through the shower plate 15, flows downward toward the substrate 7 via the top portion 2b. The reaction gas 4 is attracted by the substrate 7 while the substrate 7 is rotating, and the reaction gas 4 forms a so-called vertical flow in a region extending from the shower plate 15 to the surface of the substrate 7. When the reaction gas 4 reaches the substrate 7, the reaction gas 4 flows without turbulence as a substantially laminar flow in a horizontal direction along the upper surface of the substrate 7. As described above, the reaction gas 4 comes into contact with the surface of the substrate 7, and a vapor-phase growth film is formed on the surface of the substrate 7 by a pyrolytic reaction or a hydrogen reduction of the reaction gas 4 on the surface of the substrate 7. Furthermore, the film-forming apparatus 100 is configured so that the gap between the periphery of the substrate 7 and the liner 2 is minimized to allow the reaction gas 4 to flow more uniformly onto the surface of the substrate 7.

The reaction gas 4 not used for the vapor-phase growth reaction and the gas produced by the vapor-phase growth reaction, is exhausted from the discharge portion 6 provided at the bottom of the chamber 1.

According to the above-mentioned apparatus, the vapor-phase growth reaction is performed while the substrate 7 is rotated. The reaction gas 4 can be efficiently supplied over the whole surface of the substrate 7, and then an epitaxial film having high thickness uniformity is formed. It is noted that the film-forming rate can be increased when reaction gas 4 is continuously supplied to the surface of the substrate 7.

In the present embodiment a heating unit, wherein the heating unit consists of a main heater 9 and sub-heater 18, heats the substrate 7. In the present invention the main heater corresponds to the first heater of the present invention, and the sub-heater corresponds to the second heater in the present invention, both of these heaters are resistive heaters. The main heater 9 is provided near the substrate 7, and directly heats the substrate 7. The sub-heater 18 is provided above the main heater 9. The substrate is positioned between the main heater and sub-heater. The sub-heater 18 assists the main heater 9 and heats the substrate 7 in combination the main heater 9.

The main heater 9 is provided in the rotating cylinder 17 and heats the substrate from below. The main heater 9 includes an in-heater 9a, which is disk shaped, and an out-heater 9b, which is provided above the in-heater 9a and is a disk-shape. This is based upon the fact that the temperature is liable to be cooled due to a combination of the fast flow rate of the reaction gas 4 at the outer peripheral portion of the substrate 7, and the wall of the chamber 1 which has been cooled by cooling water. By providing the in-heater 9a and the out-heater 9b, lowering of the temperature at the outer peripheral portion of the substrate 7 is suppressed so that an even temperature distribution can be obtained.

The in-heater 9a and the out-heater 9b are arranged such that their centers are positioned on the same vertical line as the center of the substrate 7. By adopting such an arrangement, the in-heater 9a heats the whole substrate 7 while the out-heater 9b heats an outer peripheral portion of the substrate 7. Further, by arranging the out-heater 9b above the in-heater 9a, the outer peripheral portion of the substrate 7 liable to lower in temperature is effectively heated so that the temperature distribution of the substrate 7 can be made even. Incidentally, it is preferred that the temperature of the out-heater 9b be set higher than that of the in-heater 9a. Thereby, a uniform temperature across the substrate can be attained.

The in-heater 9a and the out-heater 9b are supported by an electrically conductive arm-like busbar 20. The busbar 20 is made of, for example, a SiC-coated carbon material. The busbar 20 is supported by the heater base 21 made of quartz, at the opposite side of the in-heater 9a and the out-heater 9b. The busbar 20 is connected to connecting portions 22. The connecting portions 22 are formed of a metal such as molybdenum. Electricity can be conducted from rod electrodes 23 through the busbar 20 to the in-heater 9a and the out-heater 9b. Specifically, electricity is conducted from the rod electrodes 23 to a heat source of the in-heater 9a and the out-heater 9b, and then the temperature of the heat source will increase.

The sub-heater 18 is provided around the top portion 2b of the liner 2, and is supported by the heater-supporting portion 19; the heater is connected with a supporting portion by a connecting portion (not shown). Furthermore, the heater-supporting portion is connected through the sidewall of the chamber 1 to an outer electrode. Therefore, electricity can be conducted from the outer electrode to the heater.

The substrate 7 is heated from the top surface by the sub-heater 18. The back surface of the substrate 7 is heated is also heated from the back surface by main-heater 9. That is, the substrate 7 is heated from both sides by the main-heater 9 and the first sub-heater 18a. As these heaters are the resistive heaters, the temperature of the substrate 7 can be precisely controlled.

The temperature of the chamber 1 is measured by radiation thermometers 24a and 24b. In FIG. 1, the temperature at the center of the substrate 7 is measured by the radiation thermometer 24a. The temperature of the outer position of the substrate 7 is measured by the radiation thermometer 24b. Incidentally, by changing the positions of the radiation thermometers 24a and 24b, the surface temperature of a member other than the substrate 7, for example, the susceptor 8 can be measured. Since the substrate 7 is placed on the susceptor 8, it can be thought the substrate 7 and the susceptor 8 are almost on the same position. Therefore, except for the film-forming time where a slight temperature difference is problematic, the temperature of the substrate 7 and the temperature of the susceptor 8 can be equated with each other.

The radiation thermometers 24a and 24b are positioned at the upper position of the film-forming chamber 1 as shown in FIG. 1. It is preferred that the top of the chamber and the shower plate 15 be formed of quartz, because the use of quartz prevents the temperature measurement of the radiation thermometers 24a and 24b from being affected.

After temperature measurement the data is sent to a heater output control unit (mentioned below) and then fed back to an output control unit of the in-heater 9a, the out-heater 9b, and the sub-heater 18. Incidentally, when the sub-heater 18 is composed of, for example, a first sub-heater, a second sub-heater, a third sub-heater, a fourth sub-heater, and a fifth sub-heater like another example described later, the measurement temperature data is fed back for respective output controls of the first sub-heater, the second sub-heater, the third sub-heater, the fourth sub-heater, and the fifth sub-heater.

Further, in this embodiment, it is possible that the sub-heater is composed of a plurality of resistive-heating type heaters. For example, the sub-heater can be divided to two or more sub-heaters, for example, five sub-heaters, along a vertical direction upward, that is, from the side close to the substrate 7 upward.

FIG. 2 is a cross-sectional view of a chamber in the film forming apparatus, as another example according to the present embodiment. Incidentally, a film-forming apparatus 101 shown in FIG. 2 has the same structure as that of the film-forming apparatus 100 shown in FIG. 1 except that the sub-heater 118 which is a heating unit is composed of a plurality of resistive-heating type heaters. Therefore, constituent elements common to the film-forming apparatus 101 and the film-forming apparatus 100 shown in FIG. 1 are attached with same reference numerals and explanation thereof is omitted. For example, since the control system is explained later with reference to FIG. 5, it is not shown in FIG. 2.

For example, in the film-forming apparatus 101 which is another example of this embodiment, when the sub-heater 118 is divided into five sub-heaters, the sub-heater 118 of this embodiment can have a first sub-heater 118a, a second sub-heater 118b, a third sub-heater 118c, a fourth sub-heater 118d, and a fifth sub-heater 118e. It is preferred that these sub-heaters be arranged along a vertical direction upward, namely, in this order from the side near to the substrate 7.

In the case that the sub-heater 118 is separated into five individual heaters, the first sub-heater 118a, the second sub-heater 118b, the third sub-heater 118c, the fourth sub-heater 118d, and the fifth sub-heater 118e are provided around the top portion 2b of the liner 2, and are supported by the first heater supporting portion 119a, the second heater supporting portion 119b, the third heater supporting portion 119c, the fourth heater supporting portion 119d, and the fifth heater supporting portion 119e respectively, each heater is connected with each supporting portion by connecting portions (not shown). Changing the distance between each supporting portion can modify the distance between each heater.

Furthermore, the first heater supporting portion 119a, the second heater supporting portion 119b, the third heater supporting portion 119c, the fourth heater supporting portion 119d, and the fifth heater supporting portion 119e are respectively connected through the sidewall of the chamber 1 to an outer electrode. Therefore, electricity can be individually conducted from the outer electrode through each supporting portion to each heater. As a result, each heater can be individually controlled.

The first sub-heater 118a is provided at the lowest position of the sub-heater 118 and is closest to the substrate 7 in the sub-heater 118. The substrate 7 is heated from the top surface by the first sub-heater 118a. The back surface of the substrate 7 is heated is also heated from the back surface by main-heater 9. That is, the substrate 7 is heated from both sides by the main-heater 9 and the first sub-heater 118a. As these heaters are the resistive heaters, the temperature of the substrate 7 can be precisely controlled.

The second sub-heater 118b is provided above the first sub-heater 118a. The third sub-heater 118c is provided above the second sub-heater 118b. The fourth sub-heater 118d is provided above the third sub-heater 118c. The fifth sub-heater 118e is provided above the fourth sub-heater 118d.

As the above-mentioned, the sub-heater 118 is the resistive heater. Therefore, the first sub-heater 118a heats the top portion 2b, and then the heat of the top portion 2b heats the substrate 7. When the sub-heater 18 consists of only the first sub-heater 18a, this heater can heat only a small section of the top portion 2b. That is, the temperature of the top portion 2b is distributed to the lower temperature unit, specifically to the upper side of the top portion 2b. Accordingly, in this case, the heat of the top portion 2b cannot efficiently heat the substrate 7.

The second sub-heater 118b and the third sub-heater 118c can prevent the loss of the heat from the first sub-heater 118a to the upper side of the top portion 2b of the liner 2. That is, these heaters can decrease the difference of the temperature of the top portion 2b of the liner 2. Therefore, the substrate 7 can be efficiently heated by the first sub-heater 118a. Furthermore, the combination of heaters can prevent a crack in the liner 2 caused by the difference of the temperature of the top portion 2b. The distribution of the temperature of the top portion 2b can be controlled by changing each temperature that is set in the first sub-heater 118a to the fifth sub-heater 118e, and the distance between these heaters.

Further, in this embodiment, it is possible that the sub-heater is a high-frequency induction heating type heater. Further, it is possible that the sub-heater is composed of a plurality of high-frequency induction heating type heaters.

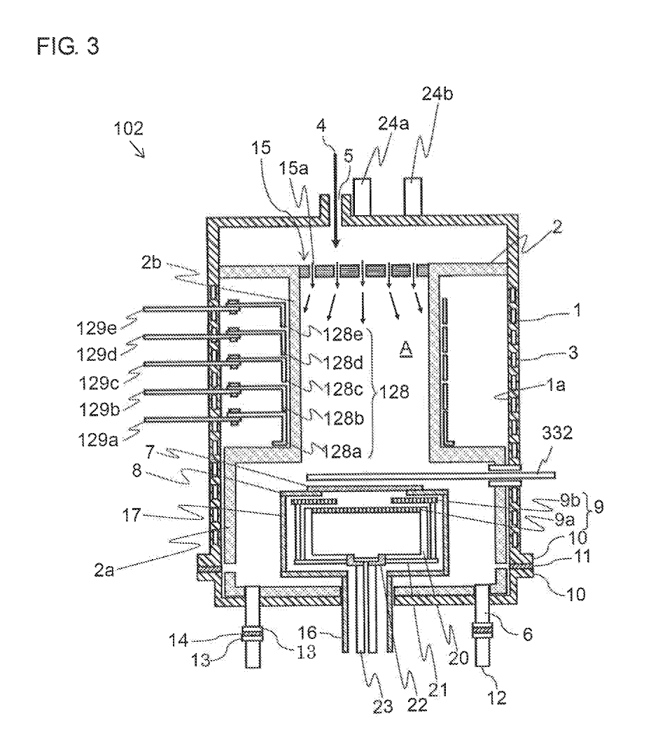

FIG. 3 is a cross-sectional view of a chamber in the film forming apparatus, as another example according to the present embodiment. Incidentally, a film-forming apparatus 102 shown in FIG. 3 has the same structure as that of the film-forming apparatus 100 shown in FIG. 1 except that the sub-heater 128, which is a heating unit, is composed of a plurality of high-frequency induction type heaters. Therefore, constituent elements common to the film-forming apparatus 101 and the film-forming apparatus 100 shown in FIG. 1 are attached with same reference numerals and explanation thereof is omitted. For example, since the control system is explained later with reference to FIG. 5, it is not shown in FIG. 3.

For example, in the film-forming apparatus 101, which is another example of this embodiment, when the sub-heater 118 is divided into five sub-heaters, the sub-heater 118 can have a first sub-heater 118a, a second sub-heater 118b, a third sub-heater 118c, a fourth sub-heater 118d, and a fifth sub-heater 118e. It is preferred that these sub-heaters be arranged along a vertical direction upward, namely, in this order from the side near to the substrate 7. The number of separated sub-heaters is not limited to five; for example, two or four sub-heaters may be used along a vertical direction upward, that is, from the side close to the substrate 7.

In the case that the sub-heater 128 is separated into five individual heaters, the first sub-heater 128a, the second sub-heater 128b, the third sub-heater 128c, the fourth sub-heater 128d, and the fifth sub-heater 128e are provided around the top portion 2b of the liner 2, and are supported by the first heater supporting portion 129a, the second heater supporting portion 129b, the third heater supporting portion 129c, the fourth heater supporting portion 129d, and the fifth heater supporting portion 129e respectively, each heater is connected with each supporting portion by connecting portions (not shown). Changing the distance between each supporting portion can modify the distance between each heater.

Furthermore, the first heater supporting portion 129a, the second heater supporting portion 129b, the third heater supporting portion 129c, the fourth heater supporting portion 129d, and the fifth heater supporting portion 129e are respectively connected through the sidewall of the chamber 1 to an outer electrode. Therefore, electricity can be individually conducted from the outer electrode through each supporting portion to each heater. As a result, each heater can be individually controlled.

The first sub-heater 128a is provided at the lowest position of the sub-heater 128 and is closest to the substrate 7 in the sub-heater 128. The substrate 7 is heated from the top surface by the first sub-heater 128a, the second sub-heater 128b, the third sub-heater 128c, the fourth sub-heater 128d, and the fifth sub-heater 128e from the upper side. The back surface of the substrate 7 is heated is also heated from the back surface by main-heater 9. That is, the substrate 7 is heated from both sides by the main-heater 9 and the first sub-heater 128a, the second sub-heater 128b, the third sub-heater 128c, the fourth sub-heater 128d, and the fifth sub-heater 128e. These heaters can be controlled individually to accurately control the temperature of the substrate 7.

As shown in FIG. 3 the second sub-heater 128b is provided above the first sub-heater 128a. The third sub-heater 128c is provided above the second sub-heater 128b. The fourth sub-heater 128d is provided above the third sub-heater 128c. As mentioned above, the sub-heater 128 comprises a plurality of high-frequency induction heaters; therefore the heating effect depends on the distance from the substrate 7. Therefore, the first sub-heater 128a, the second sub-heater 128b, third sub-heater 128c, the fourth sub-heater 128d, and the fifth sub-heater 128e differ in that heating effect from the sub-heaters to the substrate 7 lowers as the sub-heater is positioned further away from the substrate. The substrate 7 can be heated uniformly and efficiently by controlling these heaters, and the main heater 9 independently.

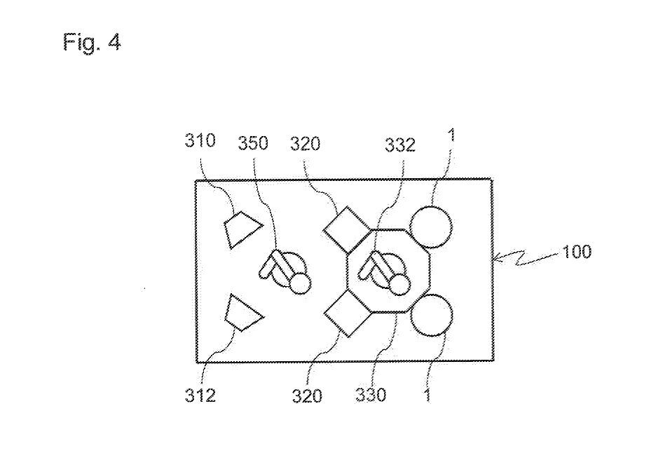

Next, the movement of the substrate 7 in the film forming apparatus 100 will be explained using FIG. 1 and FIG. 4. The movement of the substrate 7 in the film forming apparatus 101 shown in FIG. 2 and film forming apparatus 102 as shown in FIG. 3 is the same.

FIG. 4 is a plane view showing the construction of a film forming apparatus 100. As shown in FIG. 4, the film forming apparatus 100 includes the chamber 1 and substrate transfer robot control unit 332 as shown in FIG. 1, the cassette stage 310 and 312, load-lock chamber 320, transfer chamber 330, and a substrate transfer robot control unit 350.

In the cassette stage 310, a cassette is provided in which the substrate 7 is set before the film forming process. In the cassette stage 312, a cassette is provided in which the substrate 7 is set after the film forming process.

The substrate-transferring robot 350 removes the substrate 7 from the cassette stage 310 to transfer the substrate 7 to the load lock chamber 320. The substrate-transferring robot 332 is disposed in the transfer chamber 330. The transfer chamber 330 is connected with the chamber 1 where the film forming process is performed, and the substrate 7, which has been transferred to the load lock chamber 320, is transferred into the chamber 1 via the transfer chamber 330 by the substrate-transferring robot 332. It is preferred that an insertion port for the substrate-transferring robot 332 in the chamber 1 be set below the head portion 2b of the liner 2.

The substrate 7 that has been transferred into the chamber 1 is delivered to the pin from the substrate-transferring robot 332. Thereafter, the substrate 7 is placed on the susceptor 8 according to lowering of the pin.

Next, the film forming process to the substrate 7 is started, specifically; the substrate 7 is rotated at atmospheric pressure or under an appropriate reduced vacuum pressure. The main-heater 9 and the sub-heater 18 heat the substrate 7.

After the temperature of the substrate reaches the predetermined temperature, the reaction gas 4 is supplied from the supply portion 5; thereby vapor-phase growth film will be formed on the substrate 7.

After the film forming process to the substrate 7 has been completed, an output of at least one of the main heater 9 and the sub-heater 18 is turned off or lowered in order to lower the temperature of the substrate 7. When the sub-heater 18 is composed of a plurality of heaters, as previously described, an output of at least one of the main heater 9 and the respective heaters constituting the sub-heater 18 is turned off or lowered.

After it is confirmed that the temperature of the substrate 7, measured by the radiation thermometers 24a and 24b, has reached a predetermined temperature, the substrate can be transferred. A pin (not shown), capable of moving in an up and down direction is provided in the rotating shaft 16. The end of the pin extends to a substrate rising means (not shown) provided at the bottom of the rotating shaft 16. The pin can be moved up and down by the substrate rising means. The pin is used when the substrate 7 is transferred into and out of the chamber 1. The pin supports the bottom of the substrate 7, and then rises to move the substrate 101 away from the susceptor 8. The substrate 7 is then positioned above the rotating portion 104 separate from the susceptor 8 by the pin, allowing a transfer robot 332 to remove the substrate 7. The transfer robot 332 corresponds to a substrate transfer unit in the present invention.

The substrate 7 delivered to the substrate-transferring robot 332 is removed from the chamber 1, and transferred to the load lock chamber 320 via the transfer chamber 330. Next, the substrate 7 is set on the cassette arranged on the cassette stage 312 by the substrate-transferring robot 350.

Thereafter, a substrate 7 to which the film forming process should be next performed is removed from the cassette stage 310 and transferred to the load lock chamber 320 by the substrate-transferring robot 350. Next, the substrate 7 is transferred from the load lock chamber 320 to the transfer chamber 330 by the substrate-transferring robot 332, and it is further transferred into the chamber 1 where the film forming process is performed. Thereafter, the film forming process is performed in the same manner as explained above and the substrate 7 is removed from the chamber 1 to be transferred up to the cassette stage 312.

In order to transfer the substrate 7 to which the film forming process has been performed outside the chamber 1, it is necessary to wait for the temperature within the chamber 1 to lower, specifically, the temperature of the substrate 7 to a predetermined temperature or below. If the substrate 7 is transferred out of the chamber 1 before the temperature of the substrate 7 is sufficiently lowered from the film forming process temperature, there is a possibility that a crack will occur in the substrate 7 due to a temperature difference between the temperature of the substrate 7 and the temperature outside. Further, since the substrate 7 and the vapor deposition film are different in their coefficient of thermal expansion, there is a possibility that peeling or cracking will occur in the vapor deposition film.

Therefore, after the film forming process has been completed, all the outputs of the main heater 9 and the sub-heater 18 can be turned off. After it has been confirmed by the radiation thermometers 24a and 24b that the substrate 7 has lowered to the predetermined temperature, the substrate 7 is lifted up by the pin to be delivered to the substrate-transferring robot 332. Thereafter, another substrate 7 is transferred into the chamber 1 to be placed on the susceptor 8.

When all the heaters are turned off, the temperature within the chamber 1 lowers. This lowering of the temperature continues even after the substrate 7 has been removed from the chamber 1, so that the temperature of the substrate 7 becomes considerably lower than the predetermined temperature required for transferring the substrate 7 at such a time that another substrate 7 is placed on the susceptor 8. That is, a difference between the temperature within the chamber 1 and the temperature required for the film forming is large. In this state, when all the heaters are turned on, the temperature within the chamber 1 rises but a long period of time is required until the temperature of the substrate 7 reaches the film forming temperature.

The temperature within the chamber 1 is required only to be the predetermined temperature or lower than a predetermined temperature for transferring the substrate 7 in and out of the chamber 1. In view of these circumstances, the present invention has been designed so that a time required until a substrate 7, to which the film forming process should be next performed, reaches the film forming temperature can be shortened by suppressing further lowering of the temperature within the chamber 1 to a minimum.

The film-forming apparatus of the present invention has output control units which control respective outputs of a plurality of heaters independently, and the output control units turn off or lower at least one output of the plurality of heaters such as the main heater and the sub-heaters when a film forming process to a substrate is completed. For example, the output control units can turn on all the plurality of heaters. The output control units operate such that, when the temperature within the film-forming chamber reaches a temperature at which the substrate-transferring unit is operable within the film-forming chamber, an output of at least one heater of the heaters, whose output has been turned off or lowered previously, is turned on or raised and when the substrate to which the film forming process has been performed is transferred out by the substrate-transferring unit and another substrate is transferred in thereby, and an output(s) of the remaining heater(s) except for the heater whose output was turned off or lowered previously is (are) turned on or raised.

More specifically, in the film-forming apparatuses 101 and 102 shown in FIG. 2 and FIG. 3, the sub-heaters 118 and 128 are each composed of a plurality of heaters. In this case, in the sub-heater 118/128 disposed above the susceptor 8 are composed of a plurality of heaters (the first sub-heater 118a/128a, the second sub-heater 118b/128b, the third sub-heater 118c/128c, the fourth sub-heater 118d/128d, and the fifth sub-heater 118e/128e) disposed in a vertical direction, an output of at least one heater of the respective heaters constituting the sub-heater 118/128 can be turned off or lowered.

Further, the output of the main heater 9 can be turned off or lowered. When the main heater 9 is composed of a plurality of heaters (9a and 9b), an output of at least one of the respective heaters (9a and 9b) can be turned off or lowered.

When outputs of at least one heaters of heaters constituting the sub-heaters 118 and 128 are turned off or lowered, it is preferred that the heaters closest to the substrate 7, namely, the output of the first sub-heater 118a in FIG. 2 and the output of the first sub-heater 128a shown in FIG. 3 be turned off or lowered. Thereby, it is made possible to perform control for lowering the temperature in the vicinity of the substrate 7 and the susceptor 8 within the chamber 1 effectively.

The film-forming apparatuses of present embodiments will be described below in detail. The explanation is performed using the film-forming apparatus 101 shown in FIG. 2, which is one example of these embodiments.

In this embodiment, after an output of at least one heater of the plurality of heaters such as the main heater 9 and the sub-heater 118 is turned off or lowered, according to the temperature within the chamber 1, specifically, the temperature of the substrate 7 or the susceptor 8, the timing of turning on outputs of the respective heaters and magnitudes of the outputs thereof are changed. Thereby, it can be made possible to suppress further lowering of the temperature within the chamber 1 from the predetermined temperature.

FIG. 5 is a diagram showing the relationship among control systems in the film-forming apparatus 101. As shown in FIG. 5, a substrate-transferring robot control unit 401 controls an operation of the substrate-transferring robot 332. Further, the outputs of the in-heater 9a, the out-heater 9b, the first sub-heater 118a, the second sub-heater 118b, the third sub-heater 118c, the fourth sub-heater 118d, and the fifth sub-heaters 118e are controlled by output control units 402, 403, 404, 405, 406, 407, and 408, respectively. These control units control the operation of the substrate-transferring robot 332 and the outputs of the respective heaters based upon information from a temperature-measuring unit 400, respectively.

As shown in FIG. 5, the temperature-measuring unit 400 measures the temperature within the chamber 1. As the temperature, specifically, the temperature of the susceptor 8 can be adopted. Further, the temperature-measuring unit 400 may be at least one of the radiation thermometers 24a and 24b described in FIG. 2.

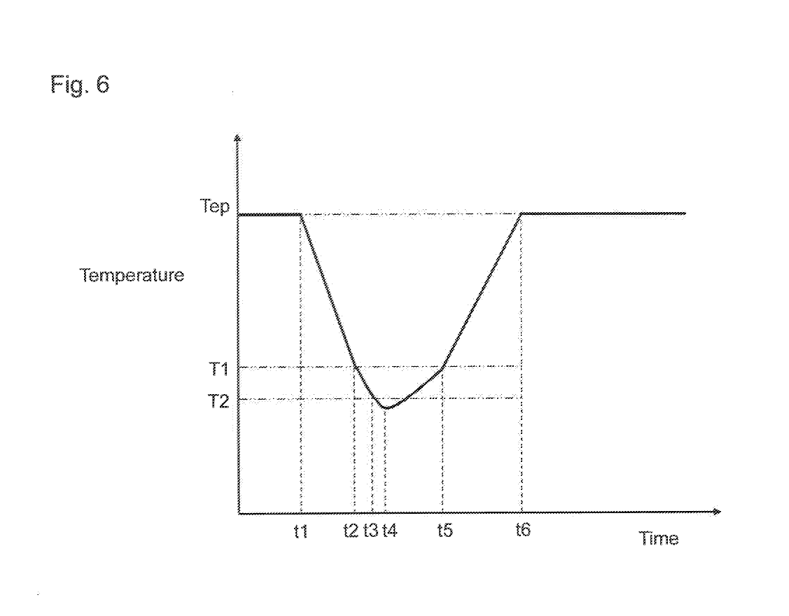

FIG. 6 is a graph illustratively showing a temporal change of the measurement result obtained by the temperature-measuring unit 400.

In FIG. 6, a temperature Tep is the film forming temperature. A completion time t1 of the film forming process to the substrate 7 can be determined, for example, by a supply time of the reaction gas 4. In this embodiment, as an example, the outputs of the in-heater 9a, the out-heater 9b, the first sub-heater 118a, the second sub-heater 118b, the third sub-heater 118c, the fourth sub-heater 118d, and the fifth sub-heater 118d are turned off at the time t1. Thereby, the temperature Tep measured by the radiation thermometer Tep will lower.

In FIG. 6, a temperature T1 is an upper limit of the temperature at which the substrate-transferring robot 332 can operate, while a temperature T2 is an upper limit of the temperature at which the substrate 7 can be transferred out of the chamber 1.

Therefore, at a time point (time t2) at which the measurement temperature obtained by the temperature-measuring unit 400 has reached T1, the substrate-transferring robot 332 enters the chamber 1. That is, in FIG. 5, when the temperature obtained by the temperature-measuring unit 400 reaches T1, a signal is transmitted to the substrate-transferring robot control unit 401. The substrate-transferring robot control unit 401 controls the substrate-transferring robot 332 to enter into the chamber 1. At a time point (time t3) at which the measurement temperature has reached T2, the substrate-transferring robot control unit 401 controls the pin to lift the substrate 7 separating the substrate 7 from the susceptor 8. Next, the substrate-transferring robot control unit 401 lifts the pin to transfer the substrate 7 to the substrate-transferring robot 332.

In this embodiment, the outputs of the second sub-heater 118b, the third sub-heater 118c, the fourth sub-heater 118d, and the fifth sub-heater 118e are turned on at the time t2. That is, in FIG. 5, when the temperature obtained by the temperature control unit 400 reaches T1, a signal is transmitted to the output control units 405, 406, 407, and 408. The output control unit 405 performs control such that the output of the second sub-heater 118b is turned on. The output control unit 406 controls such that the output of the third sub-heater 118c turns on. The output control units 407 controls such that the output of the fourth sub-heater 118d turns on. The output control unit 408 controls so that the output of the fifth sub-heater 118e turns on.

Since the second sub-heater 118b, the third sub-heater 118c, the fourth sub-heater 118d, and the fifth sub-heater 118e are positioned separated from the substrate 7, even if the outputs thereof are turned on at the time t2, the temperature of the substrate 7 continues to lower. Further, since the second sub-heater 118b, the third sub-heater 118c, the fourth sub-heater 118d, and the fifth sub-heater 118e are also separated from the position where the substrate-transferring robot 332 enters the chamber, even if the substrate-transferring robot 332 enters into the chamber 1 at the time t2, there is no possibility that the substrate-transferring robot 332 is exposed to a temperature equal to or more than the heatproof temperature of the robot. On the other hand, since the head portion 2b positioned near the second sub-heater 118b, the third sub-heater 118c, the fourth sub-heater 118d, and the fifth sub-heater 118e is heated, temperature lowering in at least one portion of the chamber 1 is suppressed.

In this embodiment, it is preferred that, after the outputs of the second sub-heater 118b, the third sub-heater 118c, the fourth sub-heater 118d, and the fifth sub-heater 118e are turned on, the outputs of these heaters are changed in a stepwise fashion for each of the heaters. Further, at this time, it is preferred that the outputs of the heaters are raised from a lower output of a heater, of the heaters that are positioned closer to the substrate 7.

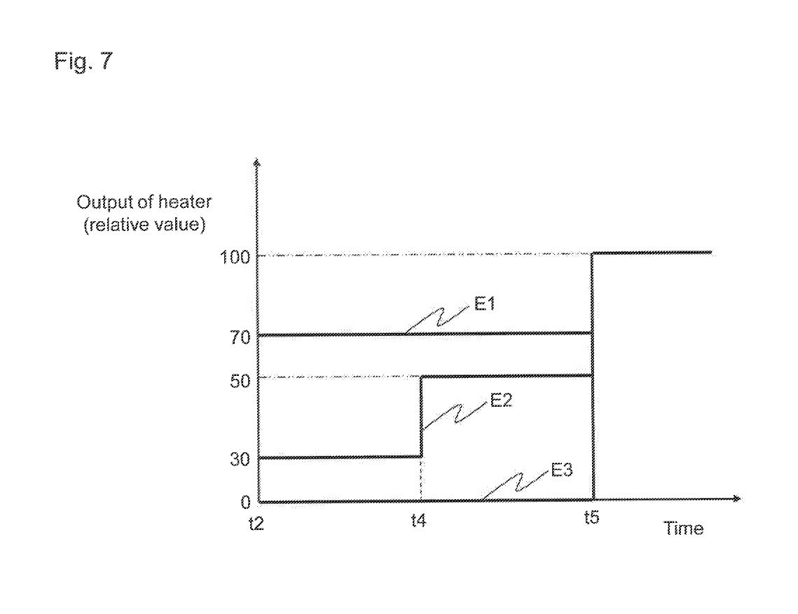

FIG. 7 is a graph showing a relationship between the outputs of the respective heaters and time. In FIG. 7, E1 denotes output change of the third sub-heater 118c, and E2 denotes output change of the second sub-heater 118b. Further, E3 denotes output changes of the first sub-heater 118a, the in-heater 9a, and the out-heater 9b. Incidentally, in this case, the outputs of the fourth sub-heater 118d and the fifth sub-heater 118e can be set to be equal to the output of the third sub-heater 118c, and the output changes thereof can be set to E1. Therefore, explanation is made using only the third sub-heater 118c, explanation of the outputs of the fourth sub-heater 118d and the fifth sub-heater 118e, which show similar output changes (E1) is omitted.

As shown in FIG. 7, in this embodiment, the second sub-heater 118b and the third sub-heater 118c are turned on at the time t2. On the other hand, the respective outputs of the first sub-heater 118a, the in-heater 9a, and the out-heater 9b remain off.

Further, the output of the third sub-heater 118c at the time t2 is more than the output of the second sub-heater 118b. It is preferred that the outputs of these heaters 118c and 118b are increased as possible in order to suppress temperature lowering of the chamber 1. However, when the outputs large are increased excessively, there is a possibility that the temperature lowering of the substrate 7 is prevented. Therefore, the output of the third sub-heater 118c positioned separated from the substrate 7, is set to, for example, 70% of the maximum output thereof, and the output of the second sub-heater 118b is set to, for example, 30% of the maximum output thereof. Thereby, it is possible to suppress the temperature lowering of the chamber 1 without preventing the temperature lowering of the substrate 7.

When the measurement temperature obtained by the temperature-measuring unit 400 reaches T2 at the time t3 in FIG. 6, the substrate 7 to which the film forming process has been performed is transferred outside the chamber 1. In this embodiment, the output of the second sub-heater 118b is raised up to, for example, 50% of the maximum output thereof at the time t4 after the time t3. Thereby, since the temperature within the chamber 1 is reversed so as to rise as a whole, as shown in FIG. 6, the measurement temperature obtained by the temperature-measuring unit 400 is raised. Incidentally, the time t4 may be a time during transferring-out of the substrate 7, or it may be a time during transferring-in of another substrate 7 to which the film forming process should be next performed.

It is necessary to place a substrate 7 to which the film forming process should be newly performed on the susceptor 8 and maintain the temperature within the chamber 1 at a temperature of T1 or lower until the substrate-transferring robot 332 exits from the chamber 1. Therefore, the measurement result obtained by the temperature-measuring unit 400 is maintained at T1 or lower by keeping the outputs of the first sub-heater 118a, the in-heater 9a, and the out-heater 9b off, until the substrate-transferring robot 332 exits from the chamber 1, and adjusting the outputs of the third sub-heater 118c and the second sub-heater 118b.

After the substrate 7 which has been newly transferred in is placed on the susceptor 8 and the substrate-transferring robot 332 exits from the chamber 1, the output of the second sub-heater 118b and the third sub-heater 118c are raised up to the maximum outputs (100%). Further, the outputs of the first sub-heater 118a, the in-heater 9a, and the out-heater 9b are turned on. Here, since it is preferred that the temperature of the substrate 7 reaches the film forming temperature Tep as fast as possible, the magnitudes of the outputs of the first sub-heater 118a, the in-heater 9a, and the out-heater 9b are set to the maximum outputs (100%) from the start.

The timing (time t5) where the outputs of all the heaters are raised up to 100% can be determined based upon the measurement result of the temperature-measuring unit 400. For example, after the substrate 7 is placed on the susceptor 8 and the substrate-transferring robot 332 exits from the chamber 1, if the measurement temperature obtained by the temperature-measuring unit 400 reaches the T1 without delay, the outputs of the respective heaters can be raised up to 100% at a time when the measurement result at the temperature-measuring unit 400 has reached T1. Specifically, this process is performed in the following manner.

As described above, when the output of the second sub-heater 118b is raised at the time t4, the temperature within the chamber 1 rises. At this time, a relationship of t′≧t″ is established by adjusting the outputs of the second sub-heater 118b and the third sub-heater 118c.

In the expression (1), t′ is a time (t5) elapsing until the measurement temperature at the temperature-measuring unit 400 reaches T1. Further, t″ is a time required from placing of the substrate 7 on the susceptor 8 up to exiting of the substrate-transferring robot 332 from the chamber 1.

It is preferred that a difference between t′ and t″ is as small as possible in order to improve the throughput of the film-forming apparatus. Here, t′ can be changed by adjusting the respective outputs of the second sub-heater 118b and the third sub-heater 118c. For example, by raising the output of the second sub-heater 118b further finely after the time t 4, or raising the output of the third sub-heater 118c in a stepwise fashion, t′ can be made short. Therefore, when the difference between t′ and t″ is large, t′ can be brought close to t″ by this method.

According to formula (1), when the temperature at the temperature-measuring unit 400 reaches T1, a signal is transmitted to the output control units 402 to 406. The output control unit 402 turns on the output of the in-heater 9a and raises the magnitude of the output up to the maximum output (100%), as shown by E3 in FIG. 7. Similarly, the output control unit 403 and the output control unit 404 turn on the output of the out-heater 9b and the output of the first sub-heater 118a, respectively, and raise the respective outputs to the maximum outputs (100%). Further, the output control unit 405 controls the second sub-heater 118b to reach the maximum output (100%), as shown by E2 in FIG. 7. Furthermore, the output control unit 406 controls the third sub-heater 118c to reach the maximum output (100%), as shown by E1 in FIG. 7.

By raising the outputs of all the heaters up to the maximum outputs (100%), the temperature within the chamber 1 rises rapidly. That is, as shown in FIG. 6, the rising ratio of the temperature at the time t5 at which the temperature has reached the temperature T1, thereafter becomes larger than the previous rising ratio. When the temperature reaches the film forming temperature Tep, the reaction gas 4 is introduced into the chamber 1 from the supply unit 5 shown in FIG. 2 so that a vapor deposition film is formed on the substrate 7.

Thus, according to the film-forming apparatus 101 of this embodiment, the timing for turning-on of the outputs, and the magnitudes of the outputs of the respective heaters can be changed in response to the temperature within the chamber 1. Thereby, since it can be suppressed that the temperature within the chamber 1 lowers largely from the upper limit (T2) of the temperature at which the substrate 7 can be transferred out of the chamber 1, the time from completion of the film forming process up to performance of the next film forming process can be suppressed to a minimum, thereby improving the throughput. As one example, by setting T1 to 1000° C., and setting T2 to 900° C., and performing temperature control, a time from completion of the film forming process at the film-forming temperature of 1600° C. up to performance of the next film forming process can be considerably shortened, and the throughput can therefore be improved.

Incidentally, in this embodiment, the number of heaters constituting the sub-heater 118 can be changed appropriately. For example, two or more heaters assisting the main heater 9 may be used. Further, the number of heaters corresponding to the second sub-heater 118b, the third sub-heater 118c, the fourth sub-heater 118d, and the fifth sub-heaters 118e may be set to any number. Regardless of the number of sub-heaters, the sub-heaters are independently temperature-controlled via supporting units supporting these sub-heaters, respectively. By increasing the number of heaters, the temperature within the chamber 1 can be controlled further, so that it becomes easy to inhibit excessive lowering of the temperature.

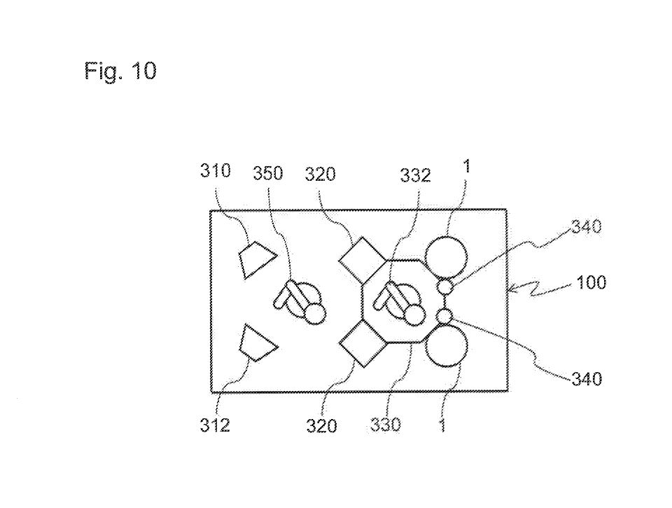

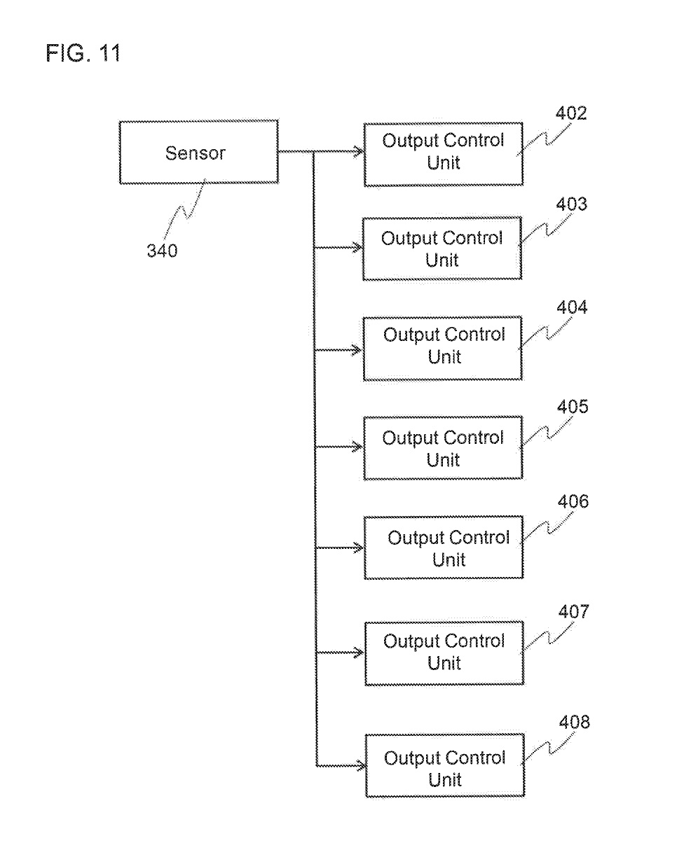

Further, in the respective examples of the above embodiments, the sub-heater is composed of the resistive-heating type heater or the high-frequency induction heating type heater, but the sub-heater of this embodiment can be composed of a combination of the resistive-heating type heater and the high-frequency induction heating type heater. Further, such a process is adopted that after the substrate, which has been newly transferred in the chamber 1, is placed on the susceptor 8 and the substrate-transferring robot is caused to exit from the chamber, the heaters are raised up to the maximum outputs. However, such a process can be adopted that after a signal indicating that the substrate-transferring robot has exited is received, the outputs of the heaters are raised. The signal can be provided by providing the position sensor indicating that the substrate-transferring robot has exited, or a sensor 340 indicating that a lid positioned between the transfer chamber and the chamber where the film forming process is performed has been closed, as shown in FIG. 10 and FIG. 11. Thereby, it is made possible to achieve improvement in throughput safely.

### Embodiment 2

A film-forming method for the formation of silicon carbide, wherein, a reaction gas is supplied into a film-forming chamber and a film of silicon carbide is formed on a substrate while the substrate is being heated by a plurality of heating units, after the formation of a silicon carbide on a substrate, at least one output of the plurality of heating units is turned off or lowered, when the temperature within the film-forming chamber reaches T1 or lower, at least one output of the plurality of heating units which has been turned off or lowered, is turned on or raised, and a substrate-transferring unit then enters the film-forming chamber, when the temperature within the film-forming chamber reaches T2 (incidentally, T1>T2) or lower, the substrate is transferred out of the film-forming chamber by the substrate-transferring unit, and another substrate is then transferred into the film-forming chamber by the substrate-transferring unit and the outputs of the remaining heating units are turned on or raised.

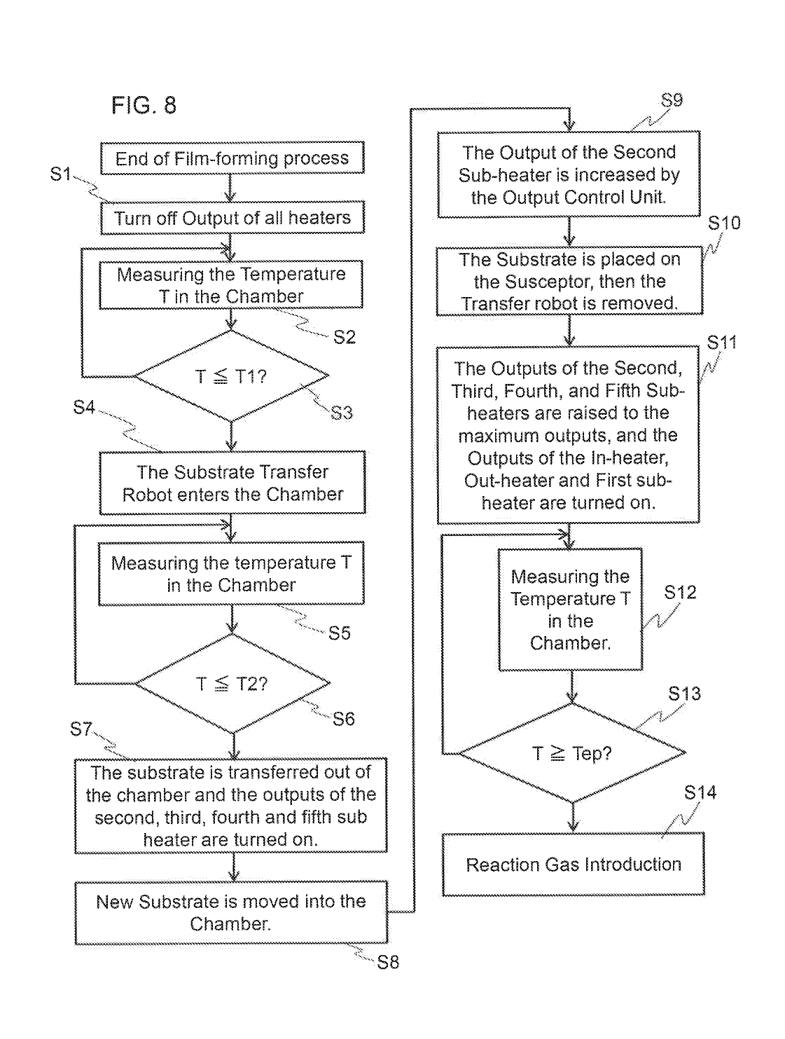

FIG. 8 is a flowchart of a film forming method according to the present embodiment. The film forming apparatus 101 in embodiment 1 performs the film forming method. The vapor-phase growth film forming method of formation of Si or SiC according to the present embodiment will be mentioned referring to FIG. 2, FIG. 4 to FIG. 8. The film forming method according to the present embodiment can also be applied to other vapor-phase growth film. Next, an example of the film-forming method in the present embodiment is described referring to FIG. 1.

A SiC wafer can be used as the substrate 7, as one example. However, the substrate 7 is not limited to a SiC wafer. The material of the substrate 7 may be, for example, Si, Sio2 (quartz) or another insulator. A highly resistive semi-insulating substrate such as GaAs (gallium arsenide) can also be used.

Firstly, the substrate 7 is transferred into the chamber 1 and then placed on the susceptor 8.

Next, the substrate 7 is rotated at atmospheric pressure or under an appropriate reduced vacuum pressure. The susceptor 8 on which the substrate 7 is placed is positioned on the upper end of the rotating cylinder 17. When the rotating cylinder 17 is rotated via the rotating shaft 16, the susceptor 8 is rotated via the rotating cylinder 17, and consequently the substrate 7 can be rotated via the susceptor 8. The number of revolutions of the substrate 7 which can be rotated at is approximately 50 rpm.

In the present embodiment, the main-heater 9 and the sub-heater 18 heat the substrate 7. In the Si vapor deposition reaction, it is necessary to heat the substrate 7 up to 1000° C. or higher, while it is necessary to heat the substrate 7 up to 1500° C. or higher in the SiC vapor deposition. It is preferred that the respective output, and therefore respective temperatures, of the heaters are set such that the output of the out-heater 9b is higher than the output of the in-heater 9a, and the output of the first sub-heater 118a is higher than the second sub-heater 118b, the output of the second sub-heater 118b is higher than the third sub-heater 118c, the output of the third sub-heater 118c is higher than the fourth sub-heater 118d, and the fourth sub-heater 118d is higher than the fifth sub-heater 118e.

As mentioned above, allowing cooling water to flow through the flow path 3 provided in the wall of the chamber 1 can prevent an excessive increase in the temperature of the film-forming chamber 1.

After it is confirmed that the temperature of the substrate 7 has reached a predetermined temperature, the number of revolutions of the substrate 7 is gradually increased. For example, the number of revolutions of the substrate 7 can be increased to 900 rpm. The reaction gas 4 is supplied from the supply portion 5.

As the reaction gas 4, trichlorosilane can be used when an Si film is formed, while when an SiC film is formed, monosilane, dichlorosilane, trichlorosilane, or silicone tetrachloride or the like can be used as an Si source, propane, ethylene or the like can be used as a C source, and HCl can be used as an additive gas, where these gases are introduced from the supply unit 5 in a state thereof mixed with hydrogen gas or argon gas serving as a carrier gas.

The reaction gas 4 passes via the through-holes 15a of the shower plate 15, and then flows into the space A in which the vapor-phase growth reaction will be performed on the substrate 7. At this time, the flow of the reaction gas 4 is straightened by the gas passing through the shower plate 15 serving as a straightening vane so that the reaction gas 4 flows substantially vertical downward toward the substrate 7 under the shower plate 15.

When the reaction gas 4 reaches the surface of the substrate 7, a thermal decomposition reaction or a hydrogen reduction reaction occurs so that a Si epitaxial film or a SiC epitaxial film is formed on the surface of the substrate 7. Surplus reaction gas 4 that isn't used for the vapor-phase growth reaction, and gas generated by the vapor-phase growth reaction, is discharged through the discharge portion 6 provided in the lower unit of the film-forming chamber 1.

The Si vapor deposition film or the SiC vapor deposition film can be formed on the substrate 7 in the above manner. After the film formation on the substrate 7 has been completed, a film forming process on another substrate 7 is performed. A process between the completion and start of the film forming process is performed according to a flowchart shown in FIG. 8.

First of all, as shown at step S1 in FIG. 8, all the heaters, namely, the in-heater 9a, the out-heater 9b, the first sub-heater 118a, the second sub-heater 118b, the third sub-heater 118c, the fourth sub-heater 118d, and the fifth sub-heater 118e are turned off.

Next, the temperature T within the chamber 1 is measured (step S2). Here, as the temperature T, the temperature of the susceptor 8 can be adopted. Further, the measurement is performed using at least one of the radiation thermometers 24a and 24b.

At step S3, determination is as to whether or not the temperature T within the chamber 1 is at the upper limit T1 of the temperature at which the substrate-transferring robot 332 is operable or less than the upper limit T1. When T>T1, the process returns to step S2 and the measurement is continued. On the other hand, when T≦T1, the control proceeds to step S4, where the substrate-transferring robot 332 is introduced into the chamber 1.

As shown in FIG. 5, the substrate-transferring robot control unit 401 performs control of the substrate-transferring robot 332. Here, the temperature-measuring unit 400 shown in FIG. 5 is provided with not only a function of causing the radiation thermometers 24a and 24b to perform the temperature measurement but also a function of performing respective determinations (S3, S6, and S13) shown in FIG. 8. When T≦T1 is determined by the temperature-measuring unit 400, a signal indicating the determination is transmitted to the substrate-transferring robot control unit 401. Thereby, the substrate-transferring robot control unit 401 controls the substrate-transferring robot 332 so as to be introduced into the chamber 1.

Subsequently, the temperature T within the chamber 1 is similarly measured at step S5 as in the step S2. Next, determination is made at step S6 as to whether or not the temperature T within the chamber 1 is the upper limit T2 of the temperature at which the substrate 7 can be transferred out of the chamber 1 or less. When T>T2 is determined, the control returns to step S5 and the measurement is continued. When T≦T2 is determined, the control proceeds to step S7, where the substrate 7 is transferred out of the chamber 1 and the respective outputs of the second sub-heater 118b, the third sub-heater 118c, the fourth sub-heater 118d and the fifth sub heat 118e are turned on. This operation is performed through the output control units 405, 406, 407, and 408 shown in FIG. 5. That is, when T≦T2 is determined at the temperature-measuring unit 400, a signal indicating the determination is transmitted to the output control units 405, 406, 407, and 408. Thereby, these output control units turn on the outputs of the second sub-heater 118b, the third sub-heater 118c, the fourth sub-heater 118d, and the fifth sub-heater 118e, respectively. Further, the output control units 405, 406, 407, and 408 can control output values of heaters corresponding thereto as shown by chart in FIG. 7. For example, the output control units 406, 407, and 408 can control the output values of the third sub-heater 118c, the fourth sub-heater 118d, and the fifth sub-heater 118e corresponding thereto as shown by E1 of the chart shown in FIG. 7, respectively.

The transferring-out of the substrate 7 from the chamber 1 is performed in the same manner as described in the first embodiment. That is, the substrate 7 is supported from below by the pin (not shown); the substrate is then lifted up and separated from the susceptor 8. After the pin is raised as it is, the substrate 7 is delivered to the substrate-transferring robot 332.

The substrate 7, which has been delivered to the substrate-transferring robot 332, is removed from the chamber 1, and is transferred to the load lock chamber 320 via the transfer chamber 330 shown in FIG. 4. Next, the substrate 7 is set in the cassette arranged on the cassette stage 312 by the substrate-transferring robot 350.

Thereafter, a substrate 7 to which the film forming process should be next performed is removed from the cassette stage 310, and it is transferred to the load lock chamber 320 by the substrate-transferring robot 350. Next, the substrate 7 is transferred from the load lock chamber 320 to the transfer chamber 330 by the substrate-transferring robot 332 and it is further transferred into the chamber 1 where the film forming process is performed (step S8).

In this embodiment, it is preferred that the outputs of the second sub-heater 118b to the fifth sub-heater 118e are raised in a stepwise fashion. Further, in this case, it is preferred that the output of the second sub-heater 118b is raised from its value lower than the value of the output of the third sub-heater 118c. It is preferred that the output of the third sub-heater 118c is raised from its value lower than the value of the output of the fourth sub-heater 118d. It is preferred that the output of the fourth sub-heater 118d is raised from its value lower than the value of the output of the fifth sub-heater 118e.

In this embodiment, after the transfer of the substrate 7 to which the film forming process should be next performed into the chamber 1 starts, the output of the second sub-heater 118b is raised as shown in FIG. 6 (step S9). Thereby, the temperature change within the chamber 1 can be reversed, that is, the temperature can rise.

Next, the substrate 7 is placed on the susceptor 8, and the substrate-transferring robot 332 is exits from the chamber 1 (step S10). Thereafter, at step S11, the outputs of the second sub-heater 118b to the fifth sub-heater 118e are raised to the maximum outputs (100%). Further, the outputs of the first sub-heater 118a, the in-heater 9a, and the out-heater 9b are turned on. The magnitudes of these outputs are raised to the maximum outputs (100%) from the start.

At step S12, the temperature T within the chamber 1 is measured in the same manner as the case of step S2 or S5 and determination is made about whether or not the temperature T is the film forming temperature Tep or higher. When T<Tep is determined, the process returns to the step S12 and the measurement is repeated. On the other hand, when T≧Tep is determined, the process proceeds to step S14, where the reaction gas 4 is introduced into the chamber 1. Thereby, a Si vapor deposition film is formed on the substrate 7.

According to this embodiment, since the timing of turning-on the outputs of the respective heaters and the magnitudes of the outputs thereof are changed according to the temperature within the chamber 1, it can be inhibited that the temperature within the chamber 1 lowers largely from the upper limit (T2) of the temperature at which the substrate 7 can be transferred out of the chamber 1. Therefore, the time elapsing from completion of the film forming process to the start of the next film forming process can be suppressed to a minimum thereby improving throughput.

Incidentally, in FIG. 8, the temperatures are measured at steps S2, S5 and S12, but such a configuration can be adopted that the temperature measurement is always performed in parallel with the respective steps S1 to S14 and determinations based upon the respective measurement results at the steps S3, S6, and S13 are made.

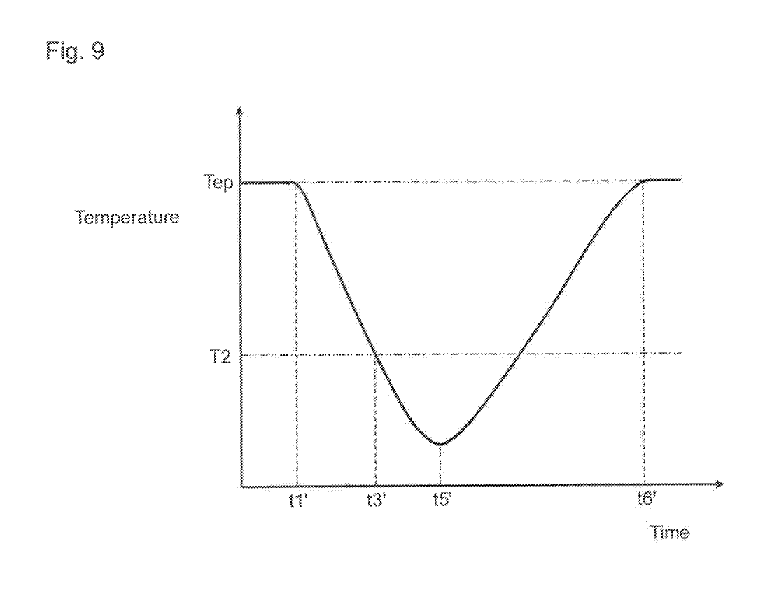

FIG. 9 is a graph of a comparative example of this embodiment, and it illustratively shows the temporal change of the measurement result obtained by the temperature-measuring unit 400. In FIG. 9, the temperature Tep denotes a film forming temperature and the temperature T2 denotes an upper limit of the temperature at which the substrate 7 can be transferred out of the chamber 1. Further, the time t1′ denotes the completion time of the film forming process and the time T3′ denotes a time at which the temperature within the chamber 1 reaches the temperature T2.

In the example shown in FIG. 9, the outputs of all the heaters at the time t1′, namely, the in-heater 9a, the out-heater 9b, the first sub-heater 118a, the second sub-heater 118b, the third sub-heater 118c, the fourth sub-heater 118d, and the fifth sub theater 118e are turned off. Then, when the temperature within the chamber 1 lowers to T2, the substrate 7 after the film forming process is transferred out of the chamber 1, and instead, a substrate 7 to which the film forming process should be next performed is transferred into the chamber 1. Next, after the substrate 7 is placed on the susceptor 8 and the substrate-transferring robot 332 is exits from the chamber 1, the outputs of all the heaters are turned on at the time t5′. The magnitudes of the outputs at this time are set to the maximum outputs (100%). When the temperature within the chamber 1 reaches the film forming temperature Tep at the time t6′, the reaction gas 4 is introduced into the chamber 1 and a vapor deposition film is formed on the substrate 7.

As described above, when the timing of turning-on of the outputs of all the heaters are set to be the same, the temperature continuously lowers until the time t5′. Therefore, there is a large gap between the temperature within the chamber 1 at the time t5′ and the temperature T2, and as a result, a long time is required to raise the temperature up to the film forming temperature Tep.

On the other hand, as in embodiment, by changing the timing of turning-on of the outputs of the heaters according to the respective heaters, and turning on some of the heaters at a time earlier than those in the example shown in FIG. 9, lowering of the temperature within the chamber 1 can be inhibited as compared to the example shown in FIG. 9. Further, when the output values of the heaters are changed in response to a situation of transferring-in/transferring-out of the substrate 7, the above-described temperature lowering can be further suppressed. That is, according to this embodiment, it is possible to shorten the time elapsing from the completion of the film forming process, to the next film forming process, as compared with the example shown in FIG. 9 thereby achieving an improvement in throughput.

Features and advantages of the present invention can be summarized as follows.

According to the present invention, such a film-forming apparatus for silicon carbide and a film-forming method for the formation of silicon carbide can be provided that the output control units operate to turn off or lower the output of at least one heating unit of a plurality of heating units when the film forming process to the substrate is completed and to turn on or raise the output of the at least one heating unit whose output has been turned off or lowered when the temperature measured by the temperature-measuring unit reaches the temperature at which the substrate-transferring unit is operable within the film-forming chamber to cause the substrate-transferring unit to transfer the substrate to which the film forming process has been performed out of the film-forming chamber, so that the time elapsing from completion of the film forming process to performance of the next film forming process can be suppressed to a minimum, thus resulting in an improvement in throughput.

The present invention is not limited to the embodiments described above and can be implemented in various modifications without departing from the spirit of the invention. For example, the above embodiment has described an example of a film-forming process while rotating the substrate in a film-forming chamber; the present invention is not limited to this. The film-forming apparatus of the present invention may be deposited on the substrate while stationary and not rotating.

In addition to the above embodiments, a vapor-phase growth system cited as the example of a film-forming apparatus in the present invention is not limited to this. Reaction gas supplied into the film-forming chamber for forming a film on its surface while heating the wafer can also be applied to other apparatus such as a CVD (Chemical Vapor Deposition) film-forming apparatus, and to form other epitaxial film in which the apparatus can transfer the substrate.

The above description of the invention has not specified apparatus constructions, control methods, etc. which are not essential to the description of the invention, since any suitable apparatus constructions, control methods, etc. can be employed to implement the invention.

Moreover, the scope of this invention encompasses all film-forming apparatus employing the elements of the invention and variations thereof, which can be designed by those skilled in the art.

What is claimed is:

1. A film-forming apparatus for the formation of silicon carbide comprising:
a film-forming chamber to which a reaction gas is supplied, where a film forming process is performed;
a temperature-measuring unit which measures a temperature within the film-forming chamber;
a plurality of heating units which are arranged inside the film-forming chamber;
an output control unit which controls respective outputs of the plurality of heating units independently;
a substrate-transferring unit which transfers a substrate to which a film forming process of silicon carbide is performed into, and out of the chamber; and
a susceptor on which the substrate is placed, the susceptor being disposed within the film-forming chamber, wherein
the output control unit turns off or lowers at least one output of the plurality of heating units when the film forming process to the substrate is completed,
when the temperature measured by the temperature-measuring unit reaches a temperature at which the substrate-transferring unit is operable within the film-forming chamber, then at least one output of the plurality of heating units which has been turned off or lowered, is turned on or raised, and
the substrate to which the film forming process has been performed is transferred out of the film-forming chamber by the substrate-transferring unit.

2. The film-forming apparatus for the formation of silicon carbide according to claim 1, wherein
the plurality of heating units has a first heating unit arranged below the susceptor and a second heating unit arranged above the susceptor; and
the output control unit turns off or lowers the output of the first heating unit when the film forming process to the substrate is completed.

3. The film-forming apparatus for the formation of silicon carbide according to claim 1, wherein
the plurality of heating units has a first heating unit arranged below the susceptor and
a second heating unit arranged above the susceptor and composed of a plurality of heating units disposed in a vertical direction; and
the output control unit turns off or lowers the output of at least one of the plurality of heating units constituting the second heating unit when the film forming process to the substrate is completed.

4. The film-forming apparatus for the formation of silicon carbide according to claim 3, wherein
the output control unit turns off or lowers the output of a heating unit of the plurality of heating units constituting the second heating unit, which is positioned nearest to the substrate when the film forming process to the substrate is completed.

5. The film-forming apparatus for the formation of silicon carbide according to claim 3, wherein
when the temperature measured by the temperature-measuring unit reaches the temperature at which the substrate-transferring unit is operable within the film-forming chamber, the output control unit turns on or raises the output of a heating unit of the plurality of heating units constituting the second heating unit, which is positioned farthest from the substrate, and
the substrate to which the film forming process has been performed is transferred out of the film-forming chamber by the substrate-transferring unit.

6. The film-forming apparatus for the formation of silicon carbide according to claim 1, further comprising a sensor which senses that the substrate to which the film forming process has been performed has been transferred out of the film-forming chamber, wherein
the output control unit receives a signal from the sensor to control the respective outputs of the plurality of heating units independently.

7. The film-forming apparatus for the formation of silicon carbide according to claim 1, wherein
the reaction gas contains at least one selected from the group consisting of monosilane, dichlorosilane, trichlorosilane, and silicone tetrachloride and at least one selected from the group consisting of propane and ethylene.

8. A film-forming method for the formation of silicon carbide, wherein,
a reaction gas is supplied into a film-forming chamber and a film of silicon carbide is formed on a substrate while the substrate is being heated by a plurality of heating units;
after the formation of a silicon carbide on a substrate, at least one output of the plurality of heating units is turned off or lowered;
when the temperature within the film-forming chamber reaches T1 or lower, at least one output of the plurality of heating units which has been turned off or lowered, is turned on or raised, and a substrate-transferring unit then enters the film-forming chamber;
when the temperature within the film-forming chamber reaches T2 (incidentally, T1>T2) or lower, the substrate is transferred out of the film-forming chamber by the substrate-transferring unit; and
another substrate is then transferred into the film-forming chamber by the substrate-transferring unit and the outputs of the remaining heating units are turned on or raised.

9. The film-forming method for the formation of silicon carbide according to claim 8, wherein
the plurality of heating units has a first heating unit arranged below a susceptor on which the substrate is placed, and
a second heating unit arranged above the susceptor, and
when a film forming process to the substrate is completed, the output of the first heating unit is turned off or lowered.

10. The film-forming method for the formation of silicon carbide according to claim 8, wherein
the plurality of heating units has a first heating unit arranged below a susceptor on which the substrate is placed, and
a second heating unit arranged above the susceptor and is composed of a plurality of heating units disposed in a vertical direction, and
when a film forming process to the substrate is completed, at least one output of the plurality of heating units constituting the second heating unit is turned off or lowered.

11. The film-forming method for the formation of silicon carbide according to claim 10, wherein
when a film forming process to the substrate is completed, an output of a heating unit of the plurality of heating units constituting the second heating unit, which is positioned nearest to the substrate, is turned off or lowered.

12. The film-forming method for the formation of silicon carbide according to claim 10, wherein
when the temperature within the film-forming chamber reaches T2 or lower, an output of a heating unit of the heating units constituting the second heating unit, which is positioned farthest from the substrate, is turned on or raised, and
the substrate to which the film forming process has been performed is transferred out of the film-forming chamber by the substrate-transferring unit.

13. The film-forming method for the formation of silicon carbide according to claim 8, wherein
all the outputs of the plurality of heating units are turned off or lowered, after a film of silicon carbide is formed on the substrate.

14. The film-forming method for the formation of silicon carbide according to claim 8, wherein
a sensor which senses the substrate transferring in or out of the film-forming chamber is used, and
when a signal from the sensor is received the outputs of the remaining heating units are turned on or raised.

15. The film-forming method for the formation of silicon carbide according to claim 8, wherein
the reaction gas contains at least one selected from the group consisting of monosilane, dichlorosilane, trichlorosilane, and silicone tetrachloride and at least one selected from the group consisting of propane and ethylene.
